(19) United States
(12) Patent Application Publication
(10) Pub. No.: US 2014/0353140 A1
(43) Pub. Date: Dec. 4, 2014

(54) METHOD FOR MANUFACTURING TRANSPARENT ELECTROCONDUCTIVE FILM

(71) Applicant: NITTO DENKO CORPORATION, Osaka (JP)

(72) Inventors: Motoki Haishi, Onomichi-shi (JP); Yusuke Yamamoto, Ibaraki-shi (JP); Tomotake Nashiki, Onomichi-shi (JP); Kazuaki Sasa, Ibaraki-shi (JP)

(73) Assignee: NITTO DENKO CORPORATION, Osaka (JP)

(21) Appl. No.: 14/361,232

(22) PCT Filed: Nov. 28, 2012
(86) PCT No.: PCT/JP2012/080710

§ 371 Date: May 28, 2014

(30) Foreign Application Priority Data
Nov. 28, 2011 (JP) 2011-258930

(51) Int. Cl. H01B 13/00; C23C 14/35; C23C 14/08

(52) U.S. Cl. CPC H01B 13/0036; C23C 14/086; C23C 14/35; H01B 13/0016
USPC 204/192.29

(57) ABSTRACT

Disclosed is a manufacturing method for a transparent electroconductive film having excellent light-transmitting properties and low specific resistance. The present invention provides a method of manufacturing a transparent electroconductive film which comprises a film substrate and a crystallized indium tin oxide layer formed on the film substrate. The method comprises: a step of placing the film substrate in a sputtering apparatus using an indium tin oxide as a target material, and depositing indium tin oxide including amorphous parts on the film substrate by a magnetron sputtering process in which a horizontal magnetic field on the target material is set to 50 mT or more; and a step of, after the step of depositing indium tin oxide including amorphous parts, subjecting the indium tin oxide including amorphous parts to a heating treatment to thereby crystallize the indium tin oxide including amorphous parts to form the crystallized indium tin oxide layer.

### TECHNICAL FIELD

The present invention relates to a method of manufacturing a transparent electroconductive film. In particular, the present invention relates to a manufacturing method for a transparent electroconductive film having excellent light-transmitting properties and low specific resistance.

### BACKGROUND ART

Magnetron sputtering is known as a manufacturing method for a transparent electroconductive film. The magnetron sputtering is a process which comprises bringing plasma into collision with a target material to cause target particles to be sputtered toward a substrate and deposited on the substrate to thereby form a film, and is characterized particularly in that a magnetic field is generated around the target material to increase a plasma density around the target material to thereby increase a film-formation (deposition) speed.

The following Patent Document 1 discloses, as one Example, a method of forming a crystalline thin film on a substrate by a magnetron sputtering process in which a horizontal magnetic field on a target material is set to 40 mT. This method is configured to form a film by a single step of, under a low pressure atmosphere, depositing a titanium dioxide as a target material onto a substrate and simultaneously crystallizing the deposited titanium dioxide. However, this method has a technical problem of failing to obtain a transparent electroconductive film with excellent light-transmitting properties and low specific resistance, using a target material consisting of indium tin oxide.

### LIST OF PRIOR ART DOCUMENTS

### Patent Documents

Patent Document 1: JP 2007-308728A

### DISCLOSURE OF THE INVENTION

### Technical Problem

It is an object of the present invention to provide a manufacturing method for a transparent electroconductive film having excellent light-transmitting properties and low specific resistance.

### Solution to the Technical Problem

The inventors found that, along with an increase in horizontal magnetic field during a step of depositing indium tin oxide including amorphous parts (i.e., partially to completely amorphous indium tin oxide), a crystal grain size of a crystalline indium tin oxide after a step of crystallizing the indium tin oxide including amorphous parts becomes larger. Based on this finding, the inventors have reached the present invention capable of obtaining a transparent electroconductive film having excellent light-transmitting properties and low specific resistance (excellent electroconductive properties).

The present invention provides a method of manufacturing a transparent electroconductive film which comprises a film substrate and a crystallized indium tin oxide layer formed on the film substrate. The method comprises: a step of placing the film substrate in a sputtering apparatus using indium tin oxide as a target material, and depositing indium tin oxide including amorphous parts on the film substrate by a magnetron sputtering process in which a horizontal magnetic field on the target material is set to 50 mT or more; and a step of, after the step of depositing indium tin oxide including amorphous parts, subjecting the indium tin oxide including amorphous parts to a heating treatment to thereby crystallize the indium tin oxide including amorphous parts to form the crystallized indium tin oxide layer. It is preferable that the step of depositing indium tin oxide including amorphous parts is performed under a pressure less than atmospheric pressure, and the step to form the crystallized indium tin oxide layer is performed under atmospheric pressure. For example, the step of depositing indium tin oxide including amorphous parts is preferably performed under a pressure of 0.1 Pa to 1 Pa.

The horizontal magnetic field is set, preferably, in the range of 80 mT to 200 mT, more preferably, in the range of 100 mT to 200 mT. The step of depositing indium tin oxide including amorphous parts is performed, preferably, at a temperature of 40° C. to 200° C., more preferably, at a temperature of 40° C. to 150° C. The step to form the crystallized indium tin oxide layer is performed, preferably, at a temperature of 120° C. to 200° C. A period of time for performing the step of depositing indium tin oxide including amorphous parts is typically set to 1 minute or less. Further, a period of time for performing the step to form the crystallized indium tin oxide layer is typically set in the range of 10 minutes to 90 minutes.

Preferably, the film substrate is formed using one selected from the group consisting of polyethylene terephthalate, polycycloolefin and polycarbonate. Preferably, the film substrate has an easy-adhesion layer provided on a surface thereof to be subjected to deposition of the indium tin oxide. Alternatively, the film substrate may have an index matching layer provided on a surface thereof to be subjected to deposition of the indium tin oxide. Alternatively, the film substrate may have a hard coat layer provided on a surface thereof to be subjected to deposition of the indium tin oxide. Preferably, the crystallized indium tin oxide layer has a thickness of 20 nm to 50 nm. Preferably, the film substrate has a thickness of 15 μm to 50 μm.

The present invention makes it possible to manufacture a transparent electroconductive film which comprises a film substrate and an indium tin oxide layer having an average crystal grain size, typically, of 150 nm or more. Preferably, the average crystal grain size is set in the range of 175 nm to 250 nm.

### Effect of the Invention

The present invention makes it possible to manufacture a transparent electroconductive film having excellent light-transmitting properties and low specific resistance.

### BRIEF DESCRIPTION OF THE DRAWINGS

FIG. 1 is a schematic diagram illustrating a sputtering apparatus for depositing indium tin oxide including amorphous parts.

FIG. 2 is a schematic diagram illustrating a heating apparatus for crystallizing the indium tin oxide.

### DESCRIPTION OF EMBODIMENTS

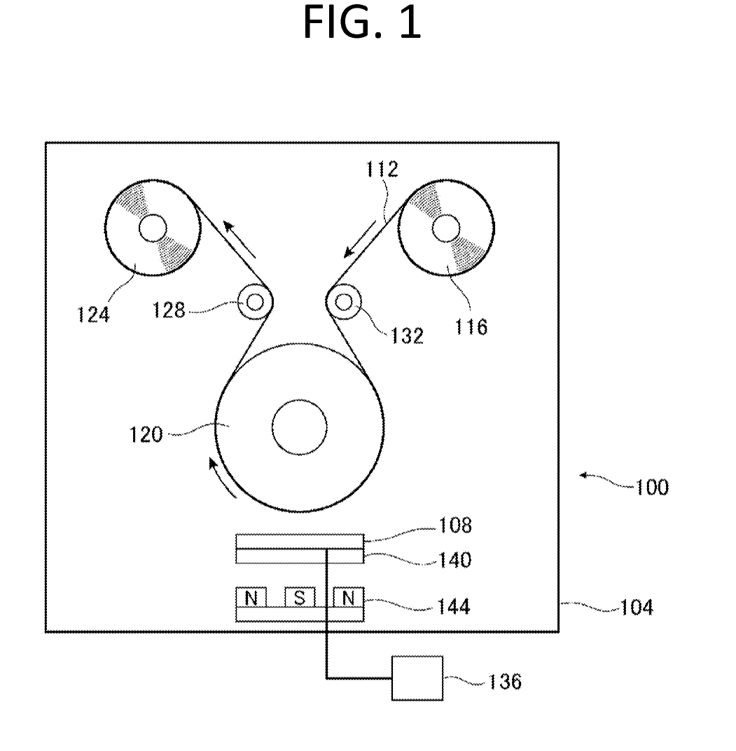

With reference to the drawings, the present invention will now be described based on one embodiment thereof. FIG. 1 is a schematic diagram illustrating a sputtering apparatus 100 for performing a step of depositing indium tin oxide including amorphous parts.

A film substrate 112 is placed in a chamber 104 of the sputtering apparatus 100 set up with a target material 108 consisting of indium tin oxide, and indium tin oxide including amorphous parts (not illustrated) is deposited on the film substrate 112 by a magnetron sputtering process utilizing a horizontal magnetic field generated on the target material 108. An intensity of the magnetic field is set to be 50 mT (millitesla) or more.

For example, as illustrated in FIG. 1, the sputtering apparatus 100 for use in the magnetron sputtering process comprises: a chamber 104 for creating an atmosphere having a low pressure of 1 Pa or less; a feed roll 116 configured to unroll the film substrate 112 therefrom; two guide rolls 128, 132 each arranged to change a delivery direction of the film substrate 112; a film-forming roll 120 whose temperature is controllable; a DC power source 136; a target material 108 disposed in opposed relation to the film-forming roll 120 and electrically connected to the DC power source 136; a cooling stage 140 configured to prevent a temperature rise of the target material 108; a magnet 144 disposed behind the target material 108 (on a side opposite to the film-forming roll 120 with respect to the target material 108) and configured to generate a horizontal magnetic field on the target material 108; and a take-up roll 124 configured to roll up the film substrate 112. In FIG. 1, the film-forming roll 120 is connected to the ground, and negative electric charges are applied to the target material 108 by the DC power source 136. Alternatively, as long as the target material 108 is set to have a potential lower than that of the film-forming roll 120, different potentials may be applied, respectively, to the film-forming roll 120 and the target material 108.

In the step of depositing indium tin oxide including amorphous parts, constituting according to this embodiment, positive ions in plasma generated under a pressure less than an atmospheric pressure, for example, of 0.1 Pa to 1 Pa, are brought into collision with the target material 108 serving as a negative electrode having a magnetic field on a surface thereof, to cause a substance (target particles) to be sputtered from a surface of the target material 108 and adhered onto the film substrate 112. For example, as a substance for generating such plasma, it is possible to use a mixed gas consisting of 99 volume % of argon gas and 1 volume % of oxygen gas. In this case, the mixed gas is sealingly contained in the chamber 104, and electrons generated by a potential difference between the film-forming roll 120 and the target material 108 are brought into collision with the mixed gas, to ionize the mixed gas to thereby generate plasma. An amount of generation of plasma can be adjusted by controlling a voltage in a range, for example, of −400 V to −100 V, while keeping an electric power of the DC power source 136 constant, to adjust a current (amount of electrons). Alternatively, the amount of generation of plasma may be adjusted in any other appropriate manner. In the magnetron sputtering process, the horizontal magnetic field allows a larger amount of plasma to be brought into collision with the target material 108 while being confined around the target material 108. An increase in amount of plasma to be brought into collision with the target material makes it possible to sputter a larger amount of target particles, so that there is a feature that it is easy to achieve a higher film-formation speed. The horizontal magnetic field also allows a temperature rise of the film substrate to be suppressed, so that there is a feature that a plastic film having poor heat resistance can be used as the film substrate.

Typically, the target material 108 is obtained by subjecting a mixed powder of indium oxide (In₂O₃) and tin oxide (SnO₂) to shaping and sintering. With a view to obtaining a transparent electroconductive film with low specific resistance, the target material 108 contains a tin oxide, typically, in an amount of 3 weight % of or more, preferably, in an amount of 5 weight % to 15 weight %. The content (weight ratio) of the tin oxide is expressed by the following formula: {(SnO₂)/((1n₂O₃+SnO₂)}×100.

In order to obtain a transparent electroconductive film with low specific resistance, it is necessary that the horizontal magnetic field on the target material 108 is set to 50 mT (millitesla) or more, preferably, in the range of 80 mT to 200 mT, more preferably, in the range of 100 mT to 200 mT.

As used herein, the term “horizontal magnetic field” means a magnetic field in a direction parallel to a surface of the target material 108 located on the side of the film substrate 112, and a maximum value of the magnetic field measured at the surface. The horizontal magnetic field can be appropriately increased by increasing a magnetic strength of the magnet 144, or setting a position of the magnet 144 to come closer to the target material. For example, a horizontal magnetic field 50 mT or more can be achieved by using a neodymium magnet made of a raw material comprising neodymium, iron and boron.

A temperature of the film substrate 112 is appropriately adjusted by the temperature of the film-forming role 120. That is, a temperature in the step of depositing indium tin oxide including amorphous parts can be set by the temperature of the film-forming role 120. For example, the temperature of the film-forming role 120 is set in the range of 40° C. to 200° C., preferably, in the range of 40° C. to 150° C. Further, depending on a film thickness, a deposition time of the indium tin oxide including amorphous parts is typically adjusted to be equal to or less than 1 minute, but may be adjusted to be greater than 1 minute.

In this embodiment, after rolling up the film substrate 112 by the take-up roll 124 during the step of depositing indium tin oxide including amorphous parts, the rolled-up film substrate 112 is transferred into another chamber to be used in a subsequent step of crystallizing indium the tin oxide including amorphous parts. Alternatively, without rolling up the film substrate 112, the film substrate 112 may be transferred into the chamber to be used in the step of crystallizing the indium tin oxide including amorphous parts, via a pressure adjusting chamber or the like. Alternatively, the step of depositing indium tin oxide including amorphous parts and the step of crystallizing the indium tin oxide including amorphous parts may be performed in a single common chamber, while adjusting the internal gas pressure of the chamber.

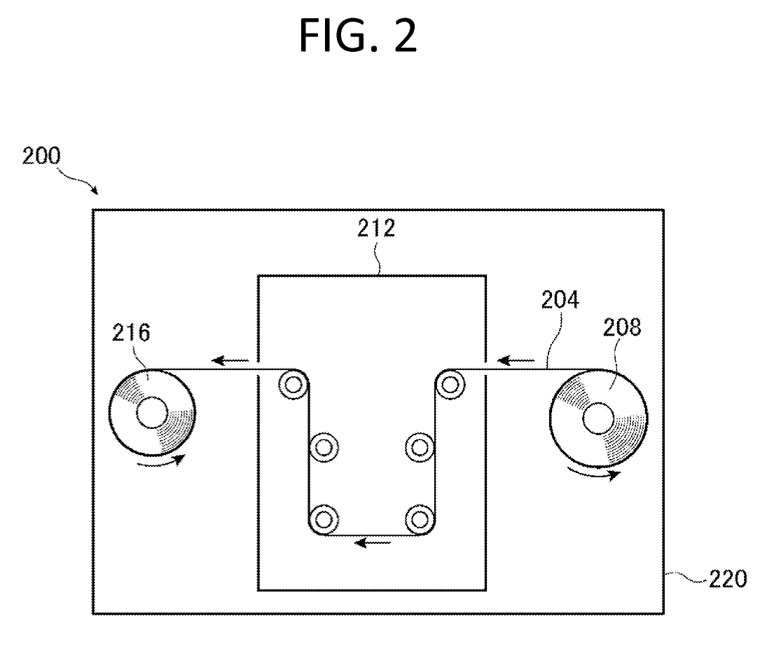

After completion of the step of depositing indium tin oxide including amorphous parts, the step of crystallizing the indium tin oxide including amorphous parts is performed by subjecting the indium tin oxide including amorphous parts to a heating treatment. FIG. 2 is a schematic diagram illustrating a heating apparatus 200 for use in performing the crystallizing step.

The heating apparatus 200 comprises: a feed roll 208 for unrolling therefrom a film substrate 204 subjected to deposition of the indium tin oxide including amorphous parts and transferred from the take-up roll 124 of the sputtering apparatus 100; a heating chamber 212 configured to subject the indium tin oxide including amorphous parts to a heating treatment to crystallize the indium tin oxide including amorphous parts; and a take-up roll 216 configured to roll up the film substrate 204. The heating apparatus 200 may further comprise a chamber 220 for safety or the like. The heating treatment is performed, for example, by passing the film substrate 204 with the indium tin oxide including amorphous parts deposited thereon, through the heating chamber 212 set to a temperature of 120° C. to 200° C. Preferably, the heating treatment is performed under a normal pressure (atmospheric pressure) atmosphere. The heating treatment under a normal pressure atmosphere allows an amount of volatile components to be generated from the film substrate to be kept low, so that it becomes easy to obtain a crystal structure with a relatively large grain size. As a result, it becomes possible to obtain a transparent electroconductive film having excellent light-transmitting properties and low specific resistance.

Depending on a crystallinity of the indium tin oxide including amorphous parts, a heating time is typically adjusted within the range of 10 minutes to 90 minutes, but may be set to a value out of the range. The crystallization of the indium tin oxide including amorphous parts can be ascertained by observing grain boundary growth in a crystal face direction by using a TEM (Transmission Electron Microscope).

As a result of performing the step of subjecting the indium tin oxide including amorphous parts to a heating treatment to crystallize the indium tin oxide including amorphous parts, a transparent electroconductive film comprising a film substrate and a crystallized indium tin oxide layer formed on the film substrate can be obtained. Regardless of changed in magnitude of the horizontal magnetic field used in the step of depositing indium tin oxide including amorphous parts, the deposited indium tin oxide obtained by the depositing step looks identical. However, when the horizontal magnetic field is increased during the step of depositing indium tin oxide including amorphous parts, a grain size in a crystal structure after the step of crystallizing the indium tin oxide including amorphous parts becomes larger. Thus, it becomes possible to obtain a transparent electroconductive film having excellent light-transmitting properties and low specific resistance (excellent electroconductive properties). This is probably because, when the horizontal magnetic field is increased, it becomes possible to reduce damage to a film due to discharge and obtain amorphous phase of indium tin oxide having less crystal nuclei, thereby allowing increase in grain size.

In view of transparence and heat resistance, as a material for the film substrate, it is preferable to use polyethylene terephthalate, polycycloolefin or polycarbonate. The film substrate may have an easy-adhesion layer, an index matching layer for adjusting a refractive index, or a hard coat layer for giving an abrasion resistant, on a surface thereof.

The film substrate has a thickness, for example, of 10 μm to 200 μm. Preferably, the thickness of the film substrate is set in the range of 15 μm to 50 μm, in view of reducing an amount of volatile components to be generated from the film substrate to improve film-formability of the indium tin oxide.

The crystallized indium tin oxide layer has a thickness, preferably, of 20 nm to 50 nm, and a specific resistance, preferably, of 3.3×10⁻⁴ Ω·cm or less, more preferably, of 2.5×10⁻⁴ Ω·cm to 3.2×10⁻⁴ Ω·cm. The crystallized indium tin oxide has an average crystal grain size, preferably, of 150 nm or more, more preferably, of 175 nm to 250 nm.

### Inventive Example 1

A film substrate composed of a 23 μm-thick polyethylene terephthalate film was placed in a sputtering apparatus set up with a target material made by preparing a mixture of 10 weight % of tin oxide and 90 weight % of indium oxide and sintering the mixture. Then, a mixed gas consisting of 99 volume % of argon gas and 1 volume % of oxygen gas was sealingly contained in a chamber of the sputtering apparatus, and an internal atmosphere of the chamber was adjusted to have a low pressure of 0.4 Pa. Under a condition that a horizontal magnetic field on the target material made by sintering was set to 50 mT, a 32 nm-thick indium tin oxide including amorphous parts was deposited on the film substrate by a magnetron sputtering process. The horizontal magnetic field was measured according to JIS C2501, using a Tesla meter (TM-701 produced by KANETEC Co., Ltd.)

Then, the indium tin oxide including amorphous parts, deposited on the film substrate was subjected to a heating treatment under a normal pressure atmosphere for 90 munities, within a heating chamber at 140° C. It was ascertained that the indium tin oxide including amorphous parts, deposited on the film substrate had been crystallized through the heating treatment.

A thickness of the crystallized indium tin oxide was measured by cross-section observation using a transmission electron microscope (H-7650 produced by Hitachi, Ltd.). A thickness of the film substrate was also measured using a film thickness meter (digital dial gauge DG-205 produced by Peacock (Ozaki Mfg. Co., Ltd).). Further, a specific resistance was calculated by multiplying a surface resistance (Ω/ (ohms per square)) measured using a four-terminal method according to JIS K7194. A result of the calculation of a specific resistance is presented in Table 1.

A crystal grain size was calculated from a photograph of a sample prepared by cutting the crystallized indium tin oxide using an ultramicrotome, wherein the photograph was taken using a transmission electron microscope (H-7650 produced by Hitachi, Ltd.) at a direct magnification of 6000 times. More specifically, the taken photograph was subjected to image analyzing processing, wherein data about crystal grain size was obtained on an assumption that the longest diameter in a grain boundary configuration is a size (nm) of each crystal grain, and expressed as a histogram by 25 nm. Then, an average value in the histogram was defined as an average grain size of the obtained crystal structure. A value of the crystal grain size is presented in Table 1.

A total light transmittance was measured according to JIS K7105, using a digital hazemeter (NDH-20D produced by Nippon Denshoku Industries Co., Ltd). A result of the measurement is presented in Table 1.

### Inventive Example 2

Except that the horizontal magnetic field was set to 80 mT, a transparent electroconductive film was prepared, and subjected to measurement of each value, in the same manner as that in Inventive Example 1. The horizontal magnetic field was modified by adjusting a position of a magnet of the sputtering apparatus. A result of the measurement is presented in Table 1.

### Inventive Example 3

Except that the horizontal magnetic field was set to 130 mT, a transparent electroconductive film was prepared, and subjected to measurement of each value, in the same manner as that in Inventive Example 1. A result of the measurement is presented in Table 1.

### Inventive Example 4

Except that the horizontal magnetic field was set to 150 mT, a transparent electroconductive film was prepared, and subjected to measurement of each value, in the same manner as that in Inventive Example 1. A result of the measurement is presented in Table 1.

### Inventive Example 5

Except that the horizontal magnetic field was set to 180 mT, a transparent electroconductive film was prepared, and subjected to measurement of each value, in the same manner as that in Inventive Example 1. A result of the measurement is presented in Table 1.

### Comparative Example

Except that the horizontal magnetic field was set to 30 mT, a transparent electroconductive film was prepared, and subjected to measurement of each value, in the same manner as that in Inventive Example 1. A result of the measurement is presented in Table 1.

TABLE 1

| | Horizontal | | | |
|---|---|---|---|---|
| | Magnetic | Specific | | Total Light |
| | Field | Resistance | Grain Size | Transmittance |
| | (mT) | (Ω · cm) | (nm) | (%) |
| Comparative | 30 | 3.5 × 10⁻⁴ | 138 | 86.4 |
| Example | | | | |
| Inventive Example 1 | 50 | 3.2 × 10⁻⁴ | 154 | 87.3 |
| Inventive Example 2 | 80 | 2.9 × 10⁻⁴ | 178 | 88.4 |
| Inventive Example 3 | 130 | 2.7 × 10⁻⁴ | 220 | 88.6 |
| Inventive Example 4 | 150 | 2.6 × 10⁻⁴ | 231 | 88.7 |
| Inventive Example 5 | 185 | 2.6 × 10⁻⁴ | 230 | 88.7 |

As shown in Table 1, when the horizontal magnetic field was set in the range of 50 mT to 185 mT, it was able to obtain a transparent electroconductive film having excellent light-transmitting properties and low specific resistance (excellent electroconductive properties) as compared to the case where the horizontal magnetic field was set to 30 mT.

### INDUSTRIAL APPLICABILITY

A transparent electroconductive film obtained by the manufacturing method of the present invention has various applications. For example, it can be used in a touch panel, preferably, a capacitive-type touch panel.

### EXPLANATION OF CODES

100: sputtering apparatus
104: chamber
108: target material
112: film substrate
116: feed roll
120: film-forming roll
124: take-up roll
128: guide roll
132: guide roll
136: DC power source
140: cooling stage
144: magnet
200: heating apparatus
204: film substrate
208: feed roll
212: heating chamber
216: take-up roll
220: chamber

1. A method of manufacturing a transparent electroconductive film which comprises a film substrate and a crystallized indium tin oxide layer formed on the film substrate, the method comprising:
a step of placing the film substrate in a sputtering apparatus using indium tin oxide as a target material, and depositing indium tin oxide including amorphous parts on the film substrate by a magnetron sputtering process in which a horizontal magnetic field on the target material is set to 50 mT or more; and
a step of, after the step of depositing the indium tin oxide including amorphous parts, subjecting the indium tin oxide including amorphous parts to a heating treatment to thereby crystallize the indium tin oxide including amorphous parts to form the crystallized indium tin oxide layer.

2. The method as defined in claim 1, wherein
the step of depositing indium tin oxide including amorphous parts is performed under a pressure less than atmospheric pressure, and the step to form the crystallized indium tin oxide layer is performed under atmospheric pressure.

3. The method as defined in claim 1, wherein the horizontal magnetic field is in the range of 80 mT to 200 mT.

4. The method as defined in claim 1, wherein the horizontal magnetic field is in the range of 100 mT to 200 mT.

5. The method as defined in claim 1, wherein the step of depositing indium tin oxide including amorphous parts is performed at a temperature of 40° C. to 200° C.

6. The method as defined in claim 1, wherein the step of depositing indium tin oxide including amorphous parts is performed at a temperature of 40° C. to 150° C.

7. The method as defined in claim 1, wherein the step to form the crystallized indium tin oxide layer is performed at a temperature of 120° C. to 200° C.

8. The method as defined in claim 1, wherein the film substrate is formed using one selected from the group consisting of polyethylene terephthalate, polycycloolefin and polycarbonate.

9. The method as defined in claim 1, wherein the film substrate has an easy-adhesion layer provided on a surface thereof to be subjected to deposition of the indium tin oxide.

10. The method as defined in claim 1, wherein the film substrate has an index matching layer provided on a surface thereof to be subjected to deposition of the indium tin oxide.

11. The method as defined in claim 1, wherein the film substrate has a hard coat layer provided on a surface thereof to be subjected to deposition of the indium tin oxide.

12. The method as defined in claim 1, wherein the crystallized indium tin oxide layer has a thickness of 20 nm to 50 nm.

13. The method as defined in claim 1, wherein the film substrate has a thickness of 15 μm to 50 μm.

14. The method as defined in claim 1, wherein the crystallized indium tin oxide has an average crystal grain size of 175 nm to 250 nm.
